(19) United States
(12) Patent Application Publication
(10) Pub. No.: US 2007/0057318 A1
(43) Pub. Date: Mar. 15, 2007

(54) Semiconductor memory device and method of production

(76) Inventors: Lars Bach, Ullersdorf (DE); Dominik Olligs, Dresden (DE); Torsten Mueller, Dresden (DE); Veronika Polei, Dresden (DE)

Correspondence Address: SLATER & MATSIL LLP, 17950 PRESTON ROAD, SUITE 1000, DALLAS, TX, 75252, US

(21) Appl. No.: 11/228,036

(22) Filed: Sep. 15, 2005

(51) Int. Cl. H01L 29/792; H01L 21/336

(52) U.S. Cl. 257/324; 438/589; 438/270; 438/287; 257/330

(57) ABSTRACT

A semiconductor substrate is provided with a recess. A memory layer or memory layer sequence is applied to sidewalls and the bottom of the recess. The memory layer is formed into two separate portions at opposite sidewalls of the recess either by reducing the memory layer to sidewall spacers or by forming sidewall spacers and removing portions of the memory layer that are not covered by the spacers. A gate electrode is applied into the recess, and source/drain regions are formed by an implantation of doping atoms adjacent to the sidewalls of the recess and the remaining portions of the memory layer. The memory layer can especially be a dielectric material suitable for charge-trapping.

### TECHNICAL FIELD

This invention concerns semiconductor memory devices, especially charge-trapping devices that are suitable for two-bit storage, and methods to produce such devices.

### BACKGROUND

Charge-trapping memory cells comprise a layer sequence of dielectric materials suitable for charge-trapping. Examples of charge-trapping memory cells are the SONOS memory cells comprising oxide-nitride-oxide layer sequences as a storage medium.

U.S. Pat. Nos. 5,768,192 and 6,011,725, which are both incorporated herein by reference, disclose charge-trapping memory cells of a special type of so-called NROM cells, which can be used to store bits of information both at the source and at the drain below the respective gate edges. NROM cells are usually programmed by channel hot electron injection. The programmed cell is read in reverse mode to achieve a sufficient two-bit separation. Erasure is performed by hot hole injection.

The transistor structure provided for charge-trapping memory cells comprises a gate dielectric that is formed by a memory layer sequence of dielectric materials, especially a memory layer of nitride that is located between boundary layers of oxide, which substitute the gate oxide. The inversion of the programming and reading direction enables the storage of two separate bits of information at each end of the transistor channel. In the programming process, charge carriers are trapped in the vicinity of one of the source/drain regions. The shrinking of the device structure in the course of a further miniaturization renders a reliable separation of the stored bits increasingly difficult. The basic idea to avoid this problem is a division of the memory layer into two separate portions that are located in the vicinities of the two source/drain regions. Thereby, a diffusion of the trapped charges within the memory layer between the storage sites is inhibited. An appropriate arrangement of two separate portions of the memory layer must take account of the relative positions of the channel region, the source/drain regions, and the gate electrode with respect to the memory layer.

### SUMMARY OF THE INVENTION

Preferred embodiments of the invention describe semiconductor memory devices that comprise separate portions of the memory layer located at both source/drain regions.

In a further aspect, an arrangement of the memory layer portions with respect to the gate electrode is achieved that is independent of the photolithography that is adopted during the manufacturing process.

In still a further aspect, the memory device is easily reproducible by means of standard semiconductor technology.

Embodiments of the invention, also provide appropriate methods to produce these memory devices by the application of standard semiconductor technology.

The memory device comprises a recess in a substrate surface and separate portions of the memory layer arranged at sidewalls of the recess.

In a first exemplary embodiment, the memory device includes a substrate of a semiconductor material having a main surface with a recess with two opposite sidewalls. Memory layers of a dielectric material that is suitable for charge-trapping are arranged at each sidewall. The memory layers are surrounded by a further dielectric material. A gate electrode is arranged in the recess and isolated from the semiconductor material by the further dielectric material. Source/drain regions are formed as doped regions in the semiconductor material adjacent to the sidewalls of the recess.

In a second exemplary embodiment, the memory device includes a substrate of a semiconductor material having a main surface with a recess with two opposite sidewalls. Spacers at the sidewalls are formed of a dielectric material that is suitable for charge-trapping. A gate electrode is located in the recess, and source/drain regions are arranged adjacent to the spacers.

In a third exemplary embodiment, the memory device includes a substrate of a semiconductor material having a main surface and a recess with two opposite sidewalls located in this surface. Memory layers formed of a nitride of the semiconductor material are arranged separately from one another at each sidewall. A gate electrode is located in the recess and is isolated from the semiconductor material and from the memory layers by an oxide of the semiconductor material. Source/drain regions are formed as doped regions in the semiconductor material adjacent to the sidewalls of the recess and are isolated from the memory layers by an oxide of the semiconductor material.

In a first exemplary method to produce the semiconductor memory device, a substrate of semiconductor material, is provided. A recess is formed in the main surface of the substrate. The recess has sidewalls and a bottom. An electrically insulating layer is formed on the sidewalls and the bottom. A memory layer of a dielectric material that is suitable for charge-trapping is applied. Portions of the memory layer are then removed, and leaving separate portions of the memory layer on sidewalls of the recess that are opposite to one another. A further electrically insulating layer covers the separate portions. A gate electrode layer is formed in the recess. Doped regions are formed in the semiconductor material adjacent to the separate portions of the memory layer.

In a second exemplary method to produce the semiconductor memory a substrate of semiconductor material is once again provided. A recess is formed in the main surface of the substrate. The recess has sidewalls and a bottom. A memory layer sequence provided as a storage means is applied at least to the sidewalls and the bottom of the recess. A spacer layer is formed over the memory layer sequence. Spacers from the spacer layer are formed at two opposite sidewalls of the recess so that the spacers partly cover the memory layer sequence. Portions of the memory layer sequence that are not covered by the spacers are removed, leaving separate portions of the memory layer sequence. The spacers are then removed and a gate electrode is formed in the recess.

These and other features and advantages of the invention will become apparent from the following brief description of the drawings, detailed description and appended claims and drawings.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a cross-section of an intermediate product of a semiconductor memory device according to a first embodiment of the invention;

FIG. 2 shows a cross-section according to FIG. 1 after the application of a memory layer;

FIG. 3 shows a cross-section according to FIG. 2 after the formation of spacerlike portions of the memory layer and an upper boundary layer;

FIG. 4 shows a cross-section according to FIG. 3 after the application of a gate electrode layer;

FIG. 5 shows a cross-section according to FIG. 4 after a partial removal of the gate electrode layer;

FIG. 6 shows a cross-section according to FIG. 5 after the application of a cover layer;

FIG. 7 shows a cross-section according to FIG. 6 after the release of the gate electrode stack;

FIG. 8 shows a cross-section according to FIG. 7 after the formation of source/drain regions;

FIG. 9 shows a cross-section of an intermediate product of a semiconductor memory device according to a second embodiment of the invention;

FIG. 10 shows a cross-section according to FIG. 9 after the formation of the recess;

FIG. 11 shows a cross-section according to FIG. 10 after the application of a memory layer sequence;

FIG. 12 shows a cross-section according to FIG. 11 after the application of a spacer layer;

FIG. 13 shows a cross-section according to FIG. 12 after the formation of sidewall spacers;

FIG. 14 shows a cross-section according to FIG. 13 after the etching of the memory layer sequence;

FIG. 15 shows a cross-section according to FIG. 14 after the removal of the spacers;

FIG. 16 shows a cross-section according to FIG. 15 after the application of gate electrode layers;

FIG. 17 shows a cross-section according to FIG. 16 after the formation of a gate electrode stack; and

FIG. 18 shows a cross-section according to FIG. 17 after the formation of source/drain regions.

The following list of reference symbols can be used in conjunction with the figures:
1substrate 12 gate electrode stack
2 shallow trench isolation 13 gate electrode spacer
3 etch stop layer 14 source/drain region
4 pad oxide 15 hard mask
5 CMP stop layer 16 resist
6 recess 17 memory layer sequence
7 electrically insulating layer 18 spacer layer
8 memory layer 19 spacer
9 further electrically insulating layer 20 re-oxidation layer
10 gate electrode layer 21 second gate electrode layer
11 cover layer

### DETAILED DESCRIPTION OF ILLUSTRATIVE EMBODIMENTS

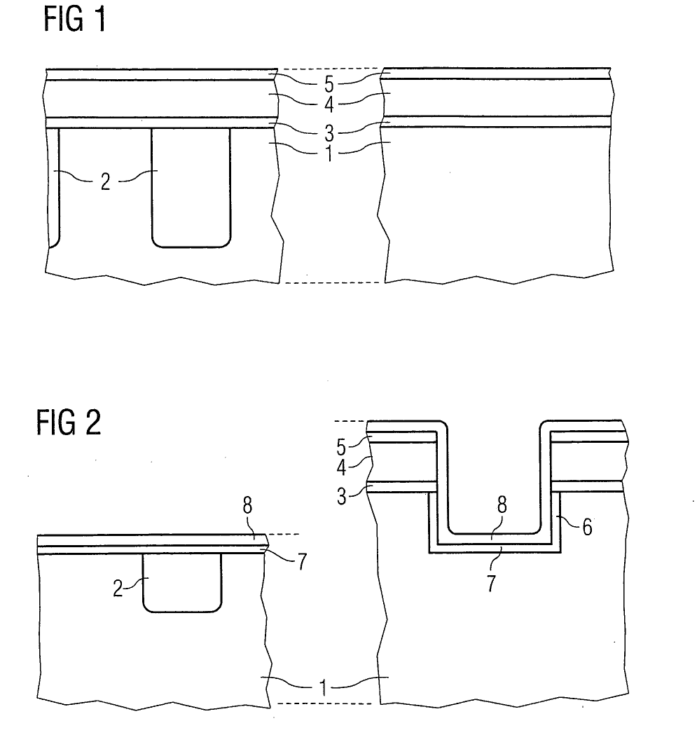

In the following, the structure of preferred embodiments of the memory device is described in conjunction with typical examples of the production method. FIG. 1 shows a cross-section of an intermediate product of a first exemplary embodiment. On the left of FIG. 1, a device section is shown, in which the substrate 1 of semiconductor material, preferably silicon, is provided with shallow trench isolations 2. The shallow trench isolations 2 may serve to electrically insulate individual memory cells from one another. The shallow trench isolations 2 can also isolate a memory cell array from peripheral areas of the device. On the right of FIG. 1, a device section is shown, where the memory cell is to be produced.

The shallow trench isolations 2 are produced at a main surface of the substrate 1. An etch stop layer 3 is applied on this substrate surface. The etch stop layer 3 may be TiN, as an example. Then, a pad oxide 4 is applied. A CMP (chemical mechanical polishing) stop layer 5 is applied to the pad oxide 4. The CMP stop layer 5 can also be TiN, for example. These layers are preferred, but can be substituted with other layers, depending on variations of this exemplary production method.

FIG. 2 shows a cross-section according to FIG. 1, after further process steps. A mask (note shown) is used to etch a recess 6 into the substrate 1 in the area of the memory cell. The etching also takes place in the area that is shown on the left side of FIG. 2. Therefore, the etch stop layer 3, the pad oxide 4, and the CMP stop layer 5 are removed in the region of the shallow trench isolations 2. An electrically insulating layer 7 is formed on the surface of the semiconductor material of the substrate 1, preferably as a thin oxide layer. The electrically insulating layer 7 is provided in the recess 6 as a lower boundary layer of a memory layer sequence, which is intended as a storage means of the memory cell. Then, a memory layer 8 is applied, which can preferably be a dielectric material that is suitable for charge-trapping, especially a nitride of the semiconductor material. The structure, so obtained, is represented in the cross-section of FIG. 2.

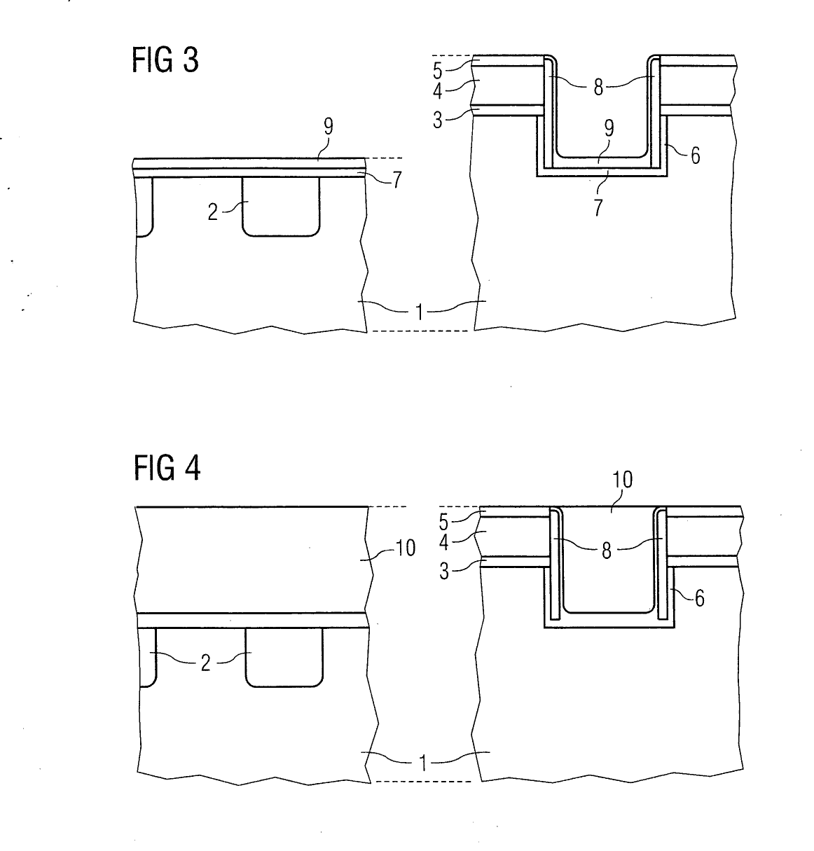

The memory layer 8 is then structured by means of a mask so that only the spacer-like residual portions shown in FIG. 3 are left on two opposite sidewalls of the recess 6. Alternatively, the memory layer can be structured by an unmasked anisotropic etch. A further electrically insulating layer 9 is applied, which covers the residual parts of the memory layer 8. The further electrically insulating layer 9 can be an oxide layer, which can be produced by a deposition of an oxide or by an oxidation of the surface. At the sidewalls of the recess 6, the layer sequence of the electrically insulating layer 7, the memory layer 8, and the further electrically insulating layer 9 forms a memory layer sequence that is appropriate for the storage of charge carriers in the memory layer 8. If the electrically insulating layers 7 and 9 are oxide, the memory layer 8 is preferably nitride. Other materials could alternatively be used.

FIG. 4 shows the cross-section of FIG. 3 after the application of a gate electrode layer 10, which can be electrically conductively doped polysilicon. If it is necessary, the surface of the gate electrode layer 10 is planarized, preferably by chemical mechanical polishing, which stops on the CMP stop layer 5.

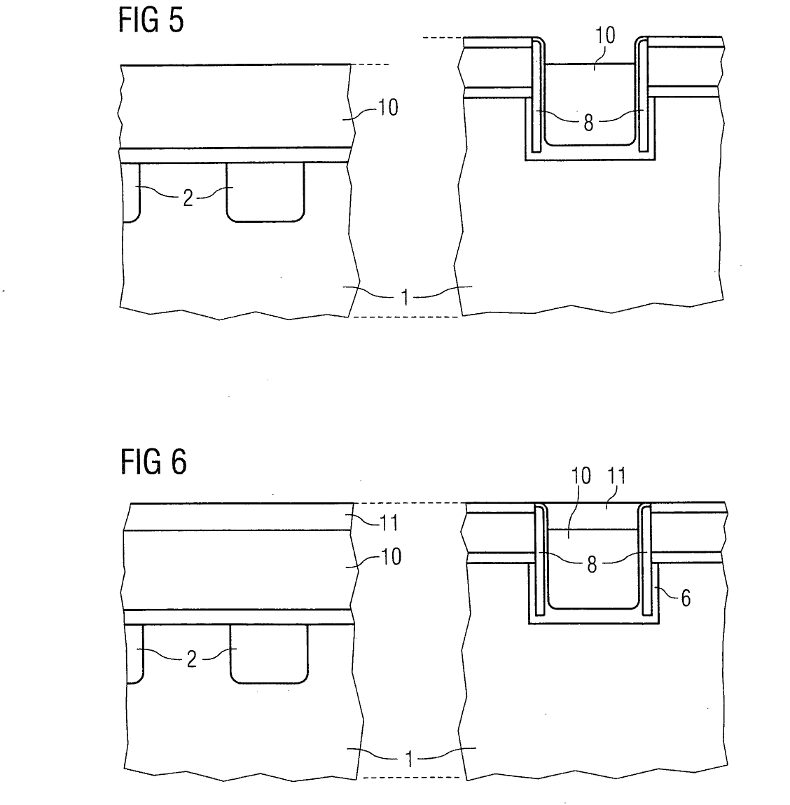

Then, the gate electrode layer 10 is partially removed, preferably etched back, to the level shown in FIG. 5.

As shown in FIG. 6, a cover layer 1, which can be a nitride of the semiconductor material (e.g., Si₃N₄), is applied onto the gate electrode layer 10. A further planarization step can be performed if it is necessary. Again, the CMP stop layer 5 serves to stop the planarization at the desired level.

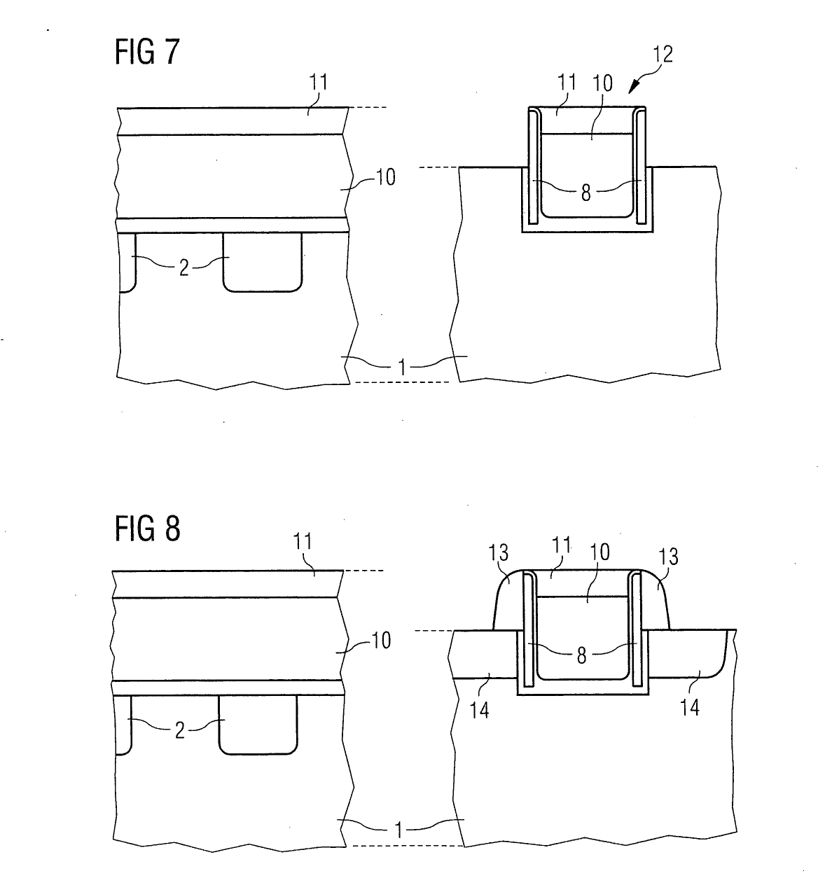

FIG. 7 shows the structure that is obtained after the removal of the remaining parts of the etch stop layer 3, the pad oxide 4, and the CMP stop layer 5. Thereby, a gate electrode stack 12, which comprises the gate electrode of the transistor structure of the memory cell, is released. The gate electrode layer 10 can be provided with further electrically conductive layers, which can be structured to wordlines connecting the gate electrodes of rows of memory cells, within a memory cell array. This is not shown in detail, because the corresponding process steps are known per se. The gate electrode stack 12 is used for a self-aligned implantation of the source/drain regions adjacent to the memory layer 8.

FIG. 8 shows the device structure according to FIG. 7, after the application of gate electrode spacers 13 to the sidewalls of the gate electrode stack 12 and the implantation of the source/drain regions 14. In an alternative embodiment, lightly doped source/drain regions can be formed first, followed by application of the gate electrode spacers 13 and implantation of the source/drain regions 14.

The gate electrode is formed by the residual part of the gate electrode layer 10. The channel region is situated below the gate electrode between the source/drain regions 14 beneath the upper boundary of the semiconductor material of the substrate 1. The local confinement of the memory layer 8 to the sidewalls of the recess 6 limits the charge storage in the course of a programming procedure to the regions that are in the vicinity of the source/drain regions 14. Therefore, this memory cell enables an improved separation of the stored bits of information near each of the source/drain regions at both ends of the channel.

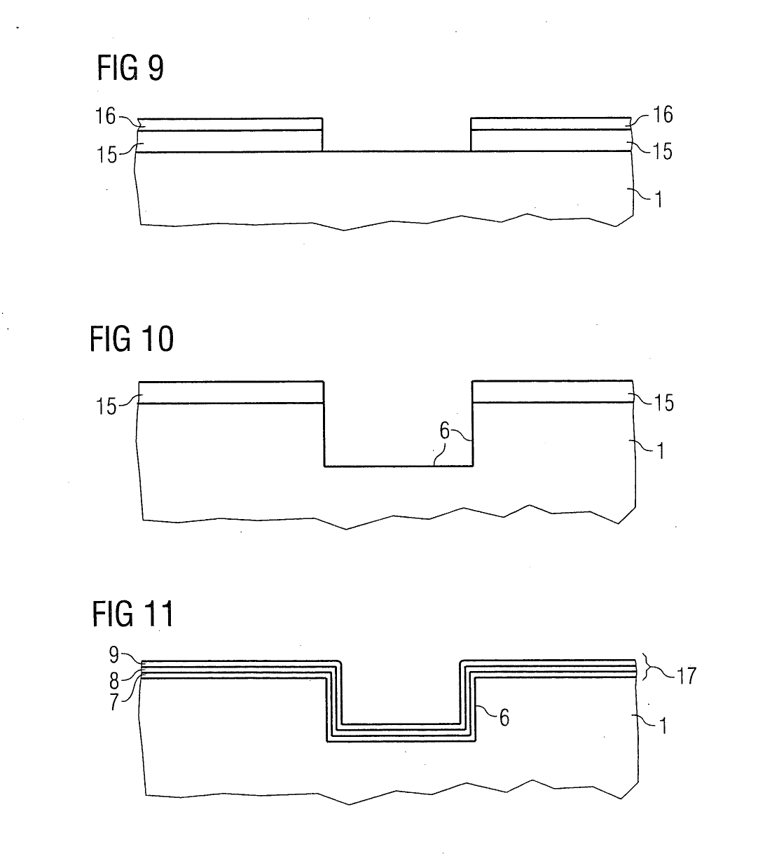

FIG. 9 shows a cross-section of an intermediate product of a second exemplary embodiment. Examples of techniques and materials discussed with respect to the first embodiment can also apply to this embodiment and vice versa. The main surface of substrate 1 is provided with a hard mask 15, which is structured by means of a resist mask 16 to have openings in the region of the memory cell that is to be produced. This is the preferred mask technique adopted here, but other techniques can also be applied.

FIG. 10 shows a cross-section according to FIG. 9 after the hard mask 15 has been used to etch a recess 6 into the surface of the substrate 1. After the removal of the hard mask 15, a memory layer sequence is applied to the substrate surface, including the sidewalls and bottom of the recess 6.

FIG. 11 shows a cross-section according to FIG. 10 after the application of the memory layer sequence 17. The memory layer sequence 17 preferably comprises an electrically insulating layer 7 as a lower boundary layer, a memory layer 8, and a further electrically insulating layer 9 as an upper boundary layer in a similar arrangement as in the embodiment that was described above. The electrically insulating layers 7 and 9 can be an oxide of the semiconductor material. The material of the memory layer 8 can be chosen to be a dielectric material that is suitable for charge-trapping, especially a nitride of the semiconductor material. Preferably, the memory layer sequence 17 is applied as an oxide-nitride-oxide layer sequence.

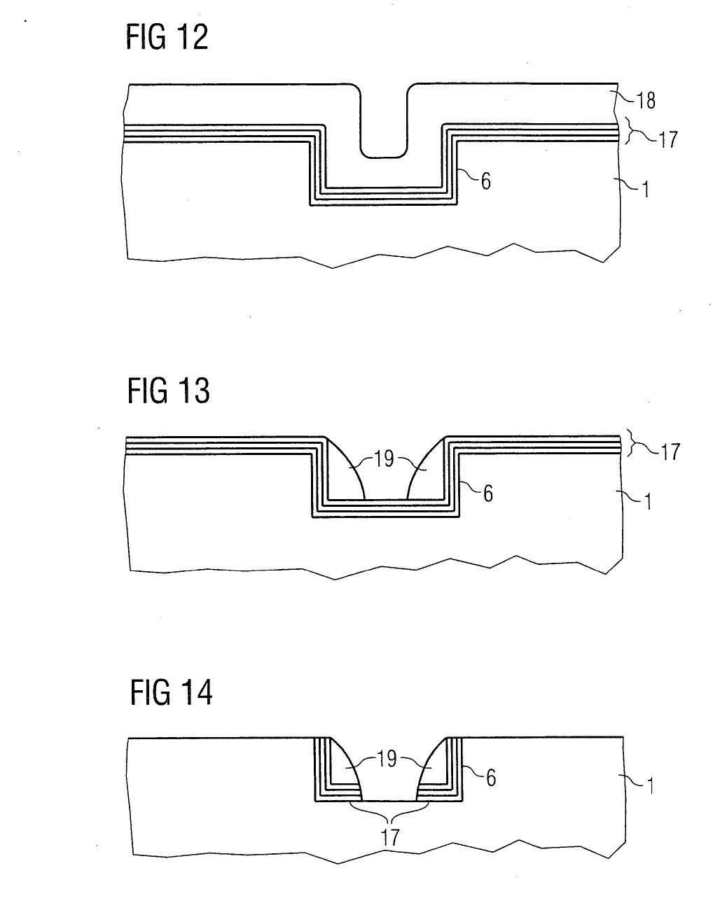

FIG. 12 shows the structure that is obtained after a spacer layer 18 has been applied, which is preferably polysilicon. The spacer layer 18 is preferably deposited conformally to the surface.

The spacer layer 18 is then etched to form sidewall spacers 19 shown in FIG. 13. In this process step, the spacer layer 18 can be etched anisotropically in standard fashion. Especially, a planar polysilicon etching can be applied, which renders spacers with triangular cross-sections. The result of the former method is represented in FIG. 13. The spacers 19 are used as a mask to remove all of the memory layer sequence 17 apart from small areas that are covered by the spacers 19.

FIG. 14 shows the result of the etching procedure and the area that is occupied by the remaining portions of the memory layer sequence 17. The memory layer 8 is then encapsulated by an electrically insulating layer, preferably a re-oxidation layer, which is produced by an oxidation of the surfaces.

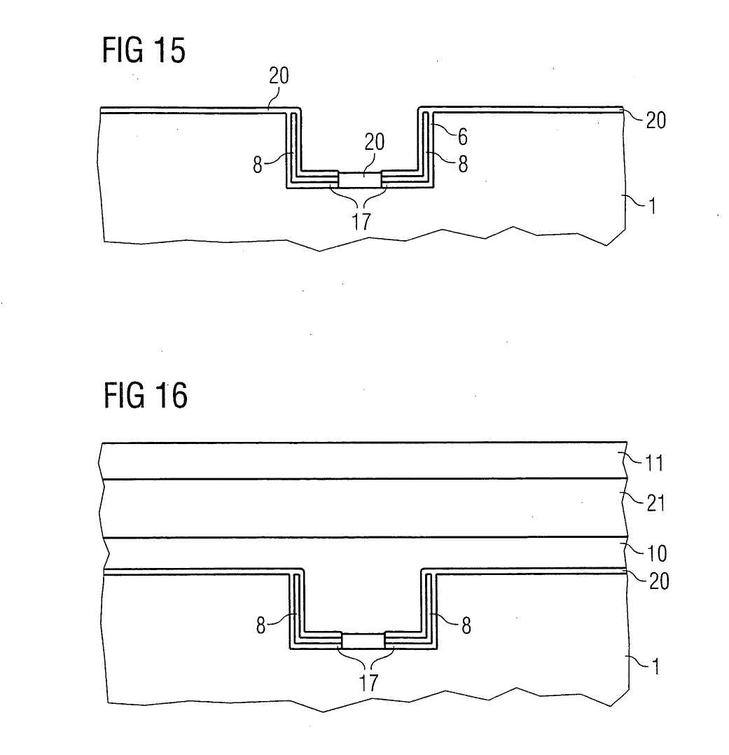

FIG. 15 shows that the re-oxidation layer 20 covers the main surface of the substrate 1 and the bottom of the recess 6 between the remaining portions of the memory layer sequence 17. Then, a gate electrode layer 10 and a cover layer 11 can be applied according to the previously described example.

FIG. 16 shows, as an example, a second gate electrode layer 21 that is arranged between the gate electrode layer 10 and the cover layer 11. The second gate electrode layer 21 can be a metal or metal silicide, which is provided to reduce the track resistance of wordlines.

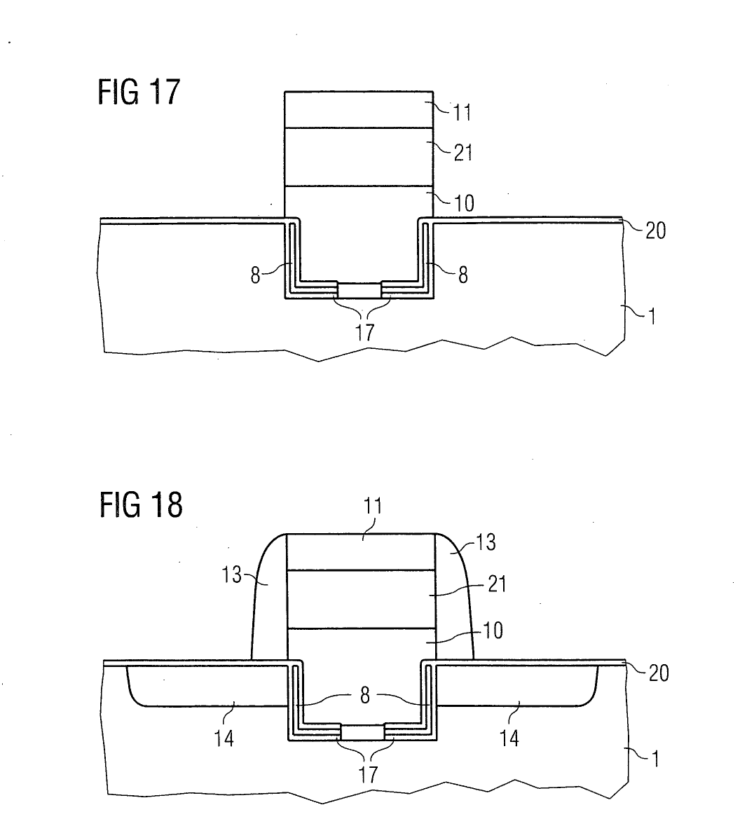

The layer sequence is then structured into a gate electrode stack or a wordline stack, as can be seen from FIG. 17. This structure is comparable to the structure shown in FIG. 7. As before, source/drain regions are implanted in self-aligned fashion, and spacers are formed on the sidewalls of the gate electrode stack.

FIG. 18 shows the memory cell structure which is obtained in this way. The source/drain regions 14 are in the immediate vicinity of the remaining portions of the memory layer 8, where charge carriers are stored in the programming process. The sidewalls of the gate electrode layer 10 and the second gate electrode layer 21 are electrically insulated by the gate electrode spacers 13. This device structure and manufacturing method render the arrangement of the remaining portions of the memory layer sequence 17, independent of influences that are due to the applied photolithographic technique.

What is claimed is:

1. A semiconductor memory device, comprising:
a semiconductor body having a main surface;
a recess in said main surface, said recess having two opposite sidewalls; and
a memory layer provided as a storage region, wherein the memory layer is arranged in two separate parts including a first at one of said sidewalls and a second part at the other of the two opposite sidewalls.

2. The semiconductor memory device according to claim 1, wherein the memory layer comprises a nitride.

3. The semiconductor memory device according to claim 1, further comprising a gate electrode disposed in said recess.

4. The semiconductor memory device according to claim 3, further comprising source/drain regions arranged in the semiconductor body adjacent to said sidewalls.

5. A semiconductor memory device, comprising:
a semiconductor body having a main surface, the semiconductor body comprising a semiconductor material;
a recess in said main surface, said recess having two opposite sidewalls;
memory layers of a dielectric material that is suitable for charge-trapping, a first of the memory layers being arranged at one of said sidewalls and a second of the memory layers being arranged at a second of the sidewalls;
a further dielectric material surrounding said memory layers;
a gate electrode arranged in said recess and isolated from said semiconductor material by said further dielectric material; and
source/drain regions being formed as doped regions in said semiconductor body adjacent to said sidewalls.

6. The semiconductor memory device according to claim 5, wherein said memory layers comprise a nitride.

7. The semiconductor memory device according to claim 5, wherein the further dielectric material comprises an oxide of said semiconductor material.

8. A semiconductor memory device, comprising:
a semiconductor body having a main surface, the semiconductor body comprising a semiconductor material;
a recess in said main surface with two opposite sidewalls;
spacers being arranged at said sidewalls, said spacers being formed of a dielectric material that is suitable for charge-trapping;
a gate electrode arranged in said recess; and
source/drain regions being arranged in the semiconductor body adjacent to said spacers.

9. The semiconductor memory device according to claim 8, wherein said spacers comprise nitride.

10. The semiconductor memory device according to claim 8, wherein said spacers are isolated from said gate electrode and said source/drain regions by an oxide of said semiconductor material.

11. A semiconductor memory device, comprising:
a semiconductor body having a main surface, the semiconductor body comprising a semiconductor material;
a recess located in said surface, said recess having two opposite sidewalls;
memory layers formed of a nitride of said semiconductor material being arranged separately from one another at each of said sidewalls;
a gate electrode being arranged in said recess, said gate electrode being isolated from said semiconductor material and from said memory layers by an oxide of said semiconductor material; and
source/drain regions being formed as doped regions in said semiconductor body adjacent to said sidewalls, said source/drain regions being isolated from said memory layers by an oxide of said semiconductor material.

12. A method of producing a semiconductor memory device, the method comprising:
providing a semiconductor body having a main surface, the semiconductor body comprising a semiconductor material;
forming a recess in said main surface, said recess having sidewalls and a bottom;
forming an electrically insulating layer on said sidewalls and said bottom;
applying a memory layer of a dielectric material that is suitable for charge-trapping;
removing portions of said memory layer to leave separate portions of said memory layer on sidewalls of said recess that are opposite to one another;
forming a further electrically insulating layer to cover said separate portions;
forming a gate electrode layer in said recess; and
forming doped regions in said semiconductor body adjacent to said separate portions of said memory layer.

13. The method according to claim 12, wherein forming said electrically insulating layer comprises forming an oxide of said semiconductor material and said further electrically insulating layer from an oxide of said semiconductor material.

14. The method according to claim 12, wherein forming said memory layer comprises forming a nitride.

15. The method according to claim 12, wherein removing portions of said memory layer to leave separate portions of said memory layer comprises forming said separate portions of said memory layer in the shape of sidewall spacers.

16. A method of producing a semiconductor memory device, the method comprising:
providing a semiconductor body with a main surface;
forming a recess in said main surface, said recess having sidewalls and a bottom;
applying a memory layer sequence at least to said sidewalls and said bottom, said memory layer sequence provided as a storage region;
applying a spacer layer onto said memory layer sequence;
forming spacers from said spacer layer at two opposite ones of said sidewalls, said spacers partly covering said memory layer sequence;
removing portions of said memory layer sequence that are not covered by said spacers thereby leaving separate portions of said memory layer sequence;
removing said spacers; and
applying a gate electrode into said recess.

17. The method according to claim 16, further comprising forming doped regions in said semiconductor body adjacent to said separate portions of said memory layer sequence.

18. The method according to claim 16, wherein forming said memory layer sequence of dielectric materials comprises forming at least one material that is suitable for charge-trapping.

19. The method according to claim 16, wherein forming said memory layer sequence of dielectric materials comprises forming said memory layer sequence of a lower boundary layer, a memory layer, and an upper boundary layer.

20. The method according to claim 19, forming said memory layer sequence of a lower boundary layer, a memory layer, and an upper boundary layer forming said lower boundary layer from oxide, said memory layer from nitride, and said upper boundary layer from oxide.
